(19) United States
(12) Patent Application Publication
(10) Pub. No.: US 2025/0203909 A1
(43) Pub. Date: Jun. 19, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Daimotsu KATO, Kawasaki (JP); Yosuke KAJIWARA, Yokohama (JP); Hiroshi ONO, Setagaya (JP); Peitsen WU, Kawasaki (JP); Ikuo FUJIWARA, Yokohama (JP); Masahiko KURAGUCHI, Yokohama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/671,005

(22) Filed: May 22, 2024

(30) Foreign Application Priority Data
Dec. 13, 2023 (JP) 2023-210463

(51) Int. Cl. H01L 29/778; H01L 29/20; H01L 29/423

(52) U.S. Cl. CPC H10D 30/475; H10D 62/8503; H10D 64/411

(57) ABSTRACT

According to one embodiment, a semiconductor device includes a first electrode, a second electrode, a third electrode including silicon, a semiconductor member, and a first insulating member. A position of the third electrode is between a position of the first electrode and a position of the second electrode in a first direction from the first electrode to the second electrode. The third electrode includes a first electrode region and a second electrode region. The semiconductor member includes a first semiconductor layer and a second semiconductor layer. The first semiconductor layer includes Alₓ₁Ga₁₋ₓ₁N (0≤x1<1), and includes a first partial region, a second partial region, a third partial region, a fourth partial region, and a fifth partial region. The second semiconductor layer includes Alₓ₂Ga₁₋ₓ₂N (0<x2≤1, x 1<x2), and includes a first semiconductor portion and a second semiconductor portion.

### CROSS-REFERENCE TO RELATED APPLICATIONS

This application is based upon and claims the benefit of priority from Japanese Patent Application No. 2023-210463, filed on Dec. 13, 2023; the entire contents of which are incorporated herein by reference.

### FIELD

Embodiments described herein relate generally to a semiconductor device.

### BACKGROUND

For example, it is desired to improve the characteristics of semiconductor devices such as transistors.

### BRIEF DESCRIPTION OF THE DRAWINGS

FIG. 1 is a schematic cross-sectional view illustrating a semiconductor device according to a first embodiment.

### DETAILED DESCRIPTION

According to one embodiment, a semiconductor device includes a first electrode, a second electrode, a third electrode including silicon, a semiconductor member, and a first insulating member. A position of the third electrode in a first direction from the first electrode to the second electrode is between a position of the first electrode in the first direction and a position of the second electrode in the first direction. The third electrode includes a first electrode region and a second electrode region. The semiconductor member includes a first semiconductor layer and a second semiconductor layer. The first semiconductor layer includes Alₓ₁Ga₁₋ₓ₁N (0≤x1<1). The first semiconductor layer includes a first partial region, a second partial region, a third partial region, a fourth partial region, and a fifth partial region. A second direction from the first partial region to the first electrode crosses the first direction. A direction from the second partial region to the second electrode is along the second direction. A direction from the third partial region to the first electrode region is along the second direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. The second semiconductor layer includes Alₓ₂Ga₁₋ₓ₂N (0<x2≤1, x 1<x2). The second semiconductor layer includes a first semiconductor portion and a second semiconductor portion. A direction from the fourth partial region to the first semiconductor portion is along the second direction. A direction from the fifth partial region to the second semiconductor portion is along the second direction. The first electrode region is between the first semiconductor portion and the second semiconductor portion in the first direction. A part of the first semiconductor portion is provided between the fourth partial region and the second electrode region in the second direction. The first insulating member is provided between the semiconductor member and the third electrode. The first electrode region and the second electrode region satisfy a first condition or a second condition. In the first condition, the second electrode region includes a first element including at least one selected from the group consisting of P and As. The first electrode region does not include the first element. In the second condition, a second concentration of the first element in the second electrode region is higher than a first concentration of the first element in the first electrode region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

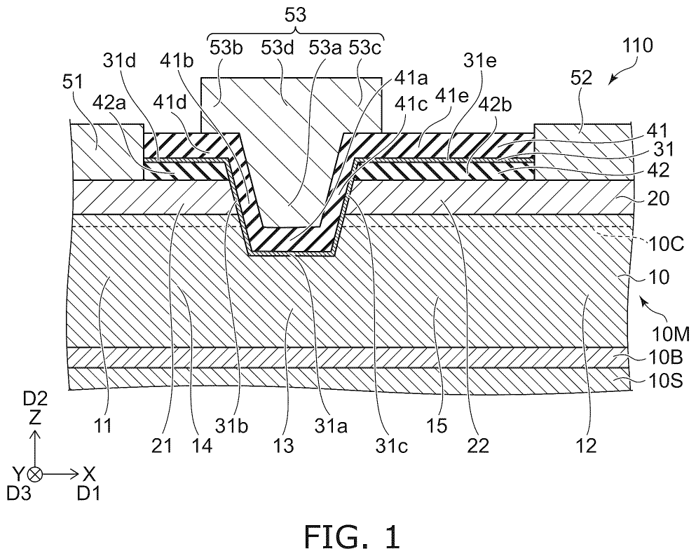

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a semiconductor member 10M, and a first insulating member 41.

A first direction D1 from the first electrode 51 to the second electrode 52 is defined as an X-axis direction. One direction perpendicular to the X-axis direction is defined as a Z-axis direction. A direction perpendicular to the X-axis direction and the Z-axis direction is a Y-axis direction.

The third electrode 53 includes silicon. The third electrode 53 may include polysilicon, for example. In the third electrode 53, silicon (polysilicon) may include impurities that provide conductivity.

A position of the third electrode 53 in the first direction D1 is between a position of the first electrode 51 in the first direction D1 and a position of the second electrode 52 in the first direction D1. The third electrode 53 includes a first electrode region 53a and a second electrode region 53b. The third electrode 53 may further include a third electrode region 53c.

The semiconductor member 10M includes a first semiconductor layer 10 and a second semiconductor layer 20. The first semiconductor layer 10 includes Alₓ₁Ga₁₋ₓ₁N (0≤x1<1). The composition ratio x1 may be, for example, not less than 0 and not more than 0.10. The first semiconductor layer 10 includes, for example, GaN. The second semiconductor layer 20 includes Alₓ₂Ga₁₋ₓ₂N (0<x2≤1, x 1<x2). The composition ratio x2 may be, for example, not less than 0.15 and not more than 0.45. The second semiconductor layer 20 includes, for example, AlGaN.

The first semiconductor layer 10 includes a first partial region 11, a second partial region 12, a third partial region 13, a fourth partial region 14, and a fifth partial region 15. A second direction D2 from the first partial region 11 to the first electrode 51 crosses the first direction D1. The second direction D2 is, for example, the Z-axis direction.

A direction from the second partial region 12 to the second electrode 52 is along the second direction D2. A direction from the third partial region 13 to the first electrode region 53a is along the second direction D2. A region overlapping the first electrode 51 in the second direction D2 corresponds to the first partial region 11. A region overlapping the second electrode 52 in the second direction D2 corresponds to the second partial region 12. A region overlapping the first electrode region 53a in the second direction D2 corresponds to the third partial region 13.

The first electrode 51, the second electrode 52, and the third electrode 53 may extend along a third direction D3. The third direction D3 crosses a plane including the first direction D1 and the second direction D2. The third direction D3 is, for example, the Y-axis direction.

A position of the fourth partial region 14 in the first direction D1 is between a position of the first partial region 11 in the first direction D1 and a position of the third partial region 13 in the first direction D1. A position of the fifth partial region 15 in the first direction D1 is between the position of the third partial region 13 in the first direction D1 and a position of the second partial region 12 in the first direction D1. Boundaries between the first partial region 11, the second partial region 12, the third partial region 13, the fourth partial region 14, and the fifth partial region 15 may be clear or unclear.

The second semiconductor layer 20 includes a first semiconductor portion 21 and a second semiconductor portion 22. A direction from the fourth partial region 14 to the first semiconductor portion 21 is along the second direction D2. A direction from the fifth partial region 15 to the second semiconductor portion 22 is along the second direction D2.

The first electrode region 53a is provided between the first semiconductor portion 21 and the second semiconductor portion 22 in the first direction D1. A part of the first semiconductor portion 21 is provided between the fourth partial region 14 and the second electrode region 53b in the second direction D2.

The first insulating member 41 is provided between the semiconductor member 10M and the third electrode 53.

The first electrode region 53a and the second electrode region 53b satisfy the following first condition or second condition. Under the first condition, the second electrode region 53b includes a first element including at least one element selected from the group consisting of P and As. Under the first condition, the first electrode region 53a does not include the first element. The first element functions as an n-type impurity, for example.

Under the second condition, a second concentration of the first element in the second electrode region 53b is higher than a first concentration of the first element in the first electrode region 53a.

For example, the first electrode 51 is electrically connected to the first semiconductor portion 21. The second electrode 52 is electrically connected to the second semiconductor portion 22.

For example, current flowing between the first electrode 51 and the second electrode 52 can be controlled by a potential of the third electrode 53. The potential of the third electrode 53 may be, for example, a potential based on a potential of the first electrode 51. The first electrode 51 is, for example, a source electrode. The second electrode 52 is, for example, a drain electrode. The third electrode 53 is, for example, a gate electrode. The semiconductor device 110 is, for example, a transistor.

The first semiconductor layer 10 includes a region facing the second semiconductor layer 20. A carrier region 10C is formed in this region. The carrier region 10C is, for example, a two-dimensional electron gas. The semiconductor device 110 is, for example, a HEMT (High Electron Mobility Transistor).

In this example, a distance between the first electrode 51 and the third electrode 53 along the first direction D1 is shorter than the distance between the third electrode 53 and the second electrode 52 along the first direction D1. It becomes easy to obtain stable operation.

As described above, the first electrode region 53a is provided between the first semiconductor portion 21 and the second semiconductor portion 22 in the first direction D1. The third electrode 53 is, for example, a recessed gate electrode. For example, the second semiconductor layer 20 is not provided under the first electrode region 53a. As a result, the carrier region 10C is not substantially formed under the first electrode region 53a. Thereby, it becomes easy to obtain a high threshold voltage. A part of the first electrode region 53a may be provided between the fourth partial region 14 and the fifth partial region 15 in the first direction D1.

For example, the first electrode region 53a is a recessed region. The second electrode region 53b is, for example, an eaves region. By providing the eaves region, the third electrode 53 can be stably formed. By providing the eaves region, for example, leakage current of the device can be reduced. For example, current collapse can be improved.

As described above, in the embodiment, the first electrode region 53a and the second electrode region 53b satisfy the above first condition or second condition. For example, the recess region (first electrode region 53a) does not include n-type impurities. On the other hand, the eaves region (second electrode region 53b) includes n-type impurities. The potential changes locally based on n-type impurities. Thereby, the carrier region 10C is easily formed under the eaves region. For example, the carrier concentration tends to be high under the eaves region. Thereby, it becomes easy to obtain low on-resistance. According to the embodiment, a semiconductor device whose characteristics can be improved can be provided. For example, by including the n-type impurity in the eaves region (second electrode region 53b), a configuration in which the length of the third electrode 53 (the length in the first direction D1) is shortened can be obtained. For example, in the eaves region including n-type impurities, the carrier concentration tends to be higher than in the case where the eaves regions do not include n-type impurities. It becomes easy to obtain low on-resistance.

In the embodiment, the third electrode 53 may further include a third electrode region 53c. A part of the second semiconductor portion 22 is provided between the fifth partial region 15 and the third electrode region 53c in the second direction D2. The third electrode region 53c includes the first element. Alternatively, the third concentration of the first element in the third electrode region 53c is higher than the first concentration. The third electrode region 53c also corresponds to the eaves region. Since the third electrode region 53c includes the first element, it becomes easier to obtain low on-resistance.

The third electrode 53 may include a second element including at least one selected from the group consisting of B and Al. The second element functions, for example, as a p-type impurity. For example, the first electrode region 53a does not substantially include the first element but includes the second element. Thereby, it becomes easier to obtain a high threshold voltage more stably, for example.

In one example, the concentration of the second element in the third electrode 53 is not less than 1×10¹⁷ cm⁻³ and not more than 1×10²¹ cm⁻³. It becomes easy to obtain high threshold voltage. Low gate resistance can be obtained. It becomes easy to obtain stable switching characteristics. As described later, the concentration of the second element in the third electrode 53 may be changed.

As mentioned above, the concentration of the first element is not uniform in the third electrode 53. In one example, at least one of the second concentration in the second electrode region 53b and the third concentration in the third electrode region 53c may be not less than 10 times and not more than 1000 times the first concentration in the first electrode region 53a.

For example, at least one of the second concentration and the third concentration may be not less than 1×10¹⁶ cm⁻³ and not more than 1×10²¹ cm⁻³. For example, the first concentration may be less than 1×10¹⁶ cm⁻³.

As shown in FIG. 1, the third electrode 53 may further include a fourth electrode region 53d. The fourth electrode region 53d is provided between the second electrode region 53b and the third electrode region 53c in the first direction D1. In one example, the fourth electrode region 53d includes the first element. Alternatively, a fourth concentration of the first element in the fourth electrode region 53d is higher than the first concentration in the first electrode region 53a.

In another example, the fourth electrode region 53d does not include the first element. Alternatively, the fourth concentration of the first element in the fourth electrode region 53d is lower than the second concentration in the second electrode region 53b. The fourth concentration is lower than the third concentration in the third electrode region 53c.

For example, the first electrode region 53a may include a second element (including at least one selected from the group consisting of B and Al). It becomes easy to obtain high threshold voltage. In one example of this case, for example, the second electrode region 53b does not include the second element. Alternatively, the concentration of the second element in the second electrode region 53b may be lower than the concentration of the second element in the first electrode region 53a. In this case, for example, the second concentration of the first element in the second electrode region 53b may be higher than the concentration of the second element in the second electrode region 53b. It becomes easier to obtain a lower on-current.

In one example where the first electrode region 53a includes the second element (including at least one selected from the group consisting of B and Al), the fourth electrode region 53d does not include the second element. Alternatively, the concentration of the second element in the fourth electrode region 53d may be lower than the concentration of the second element in the first electrode region 53a.

For example, the fourth concentration of the first element in the fourth electrode region 53d may be higher than the concentration of the second element in the fourth electrode region 53d. It becomes easy to obtain low gate resistance. Switching characteristics are easy to stabilize.

As shown in FIG. 1, for example, the first insulating member 41 includes a first insulating region 41a, a second insulating region 41b, and a third insulating region 41c. The first insulating region 41a is provided between the third partial region 13 and the first electrode region 53a in the second direction D2. The second insulating region 41b is provided between the first semiconductor portion 21 and the first electrode region 53a in the first direction D1. The third insulating region 41c is provided between the first electrode region 53a and the second semiconductor portion 22 in the first direction D1. At least a part of these insulating regions function as a gate insulating film.

The first insulating member 41 may further include a fourth insulating region 41d and a fifth insulating region 41e. At least a part of the fourth insulating region 41d is provided between the first semiconductor portion 21 and the second electrode region 53b in the second direction D2. At least a part of the fifth insulating region 41e is provided between the second semiconductor portion 22 and the third electrode region 53c in the second direction D2.

The first insulating member 41 includes silicon and oxygen, for example. The first insulating member 41 includes silicon oxide, for example. Stable insulation can be obtained.

As shown in FIG. 1, the semiconductor device 110 may further include a first compound member 31. The first compound member 31 includes Al_{z1}Ga_{1-z1}N (0<z1≤1, x2<z1). The composition ratio z1 may be, for example, not less than 0.8 and not more than 1. The first compound member 31 may include, for example, AlN. The first compound member 31 includes a first compound region 31a. The first compound region 31a is provided between the third partial region 13 and the first insulating region 41a. By providing the first compound region 31a, higher mobility can be obtained. Lower on-resistance can be obtained.

The first compound member 31 may further include a second compound region 31b and a third compound region 31c. The second compound region 31b is provided between the first semiconductor portion 21 and the second insulating region 41b. The third compound region 31c is provided between the third insulating region 41c and the second semiconductor portion 22. Fixed charges are less likely to occur between the second compound region 31b and the first semiconductor portion 21. Fixed charges are less likely to occur between the third compound region 31c and the second semiconductor portion 22. It becomes easy to obtain high threshold voltage. Lower on-resistance can be obtained. By the second compound region 31b and the third compound region 31c, diffusion of the second element into the second semiconductor portion 22 during the manufacturing process can be easily suppressed. It becomes easy to obtain a stable device.

The first compound member 31 may further include a fourth compound region 31d and a fifth compound region 31e. The fourth compound region 31d is provided between the first semiconductor portion 21 and the fourth insulating region 41d in the second direction D2. The fifth compound region 31e is provided between the second semiconductor portion 22 and the fifth insulating region 41e in the second direction D2. By providing the fourth compound region 31d and the fifth compound region 31e, for example, it is easy to suppress the first element from diffusing into the second semiconductor layer 20 during the manufacturing process. It becomes easy to obtain a stable device.

The semiconductor device 110 may further include a second insulating member 42. The second insulating member 42 includes a first insulating portion 42a and a second insulating portion 42b. The first semiconductor portion 21 is provided between the fourth partial region 14 and the first insulating portion 42a in the second direction D2. In this example, the first semiconductor portion 21 is provided between the fourth partial region 14 and the fourth compound region 31d in the second direction D2. The second semiconductor portion 22 is provided between the fifth partial region 15 and the second insulating portion 42b in the second direction D2. In this example, the second semiconductor portion 22 is provided between the fifth partial region 15 and the fifth compound region 31e in the second direction D2.

The second insulating member 42 includes, for example, nitrogen. The second insulating member 42 includes, for example, nitrogen and silicon. By providing the second insulating member 42, for example, the second semiconductor layer 20 is stabilized. The second insulating member 42 functions, for example, as a protective film.

The semiconductor device 110 may further include a base 10S and a nitride layer 10B. The base 10S is, for example, a substrate. The base 10S may be, for example, a silicon substrate. The base 10S may be, for example, a GaN substrate. The nitride layer 10B is provided between base 10S and semiconductor member 10M. The nitride layer 10B is, for example, a buffer layer. The nitride layer 10B includes, for example, Ga, Al, and nitrogen. For example, the nitride layer 10B is provided on the base 10S. The first semiconductor layer 10 is provided on the nitride layer 10B. The second semiconductor layer 20 is provided on the first semiconductor layer 10.

In the embodiment, the first element in the third electrode 53 may be introduced by, for example, ion implantation. For example, ion implantation using a mask may be used. The concentration distribution of the first element in the third electrode 53 may be obtained by controlling the depth in ion implantation.

The second element in the third electrode 53 may be introduced into the third electrode 53 by forming a silicon film or the like including the second element. The second element may be introduced into the third electrode 53 by ion implantation.

In the embodiments, information regarding the composition of the material is obtained by SIMS (Secondary Ion Mass Spectrometry), EDX (Energy dispersive X-ray spectroscopy), or the like. In the embodiments, information regarding length and thickness is obtained by electron microscopy or the like.

The embodiments may include the following Technical proposals:

### Technical Proposal 1

A semiconductor device, comprising:
a first electrode;
a second electrode;
a third electrode including silicon, a position of the third electrode in a first direction from the first electrode to the second electrode being between a position of the first electrode in the first direction and a position of the second electrode in the first direction, the third electrode including a first electrode region and a second electrode region;
a semiconductor member including a first semiconductor layer and a second semiconductor layer,
   the first semiconductor layer including Alₓ₁Ga₁₋ₓ₁N (0≤x1<1), the first semiconductor layer including a first partial region, a second partial region, a third partial region, a fourth partial region, and a fifth partial region, a second direction from the first partial region to the first electrode crossing the first direction, a direction from the second partial region to the second electrode being along the second direction, a direction from the third partial region to the first electrode region being along the second direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction,
   the second semiconductor layer including Alₓ₂Ga₁₋ₓ₂N (0<x2≤1, x 1<x2), the second semiconductor layer including a first semiconductor portion and a second semiconductor portion, a direction from the fourth partial region to the first semiconductor portion being along the second direction, a direction from the fifth partial region to the second semiconductor portion being along the second direction, the first electrode region being between the first semiconductor portion and the second semiconductor portion in the first direction, a part of the first semiconductor portion being provided between the fourth partial region and the second electrode region in the second direction; and
a first insulating member provided between the semiconductor member and the third electrode,
the first electrode region and the second electrode region satisfying a first condition or a second condition,
in the first condition, the second electrode region including a first element including at least one selected from the group consisting of P and As, and the first electrode region not including the first element, and
in the second condition, a second concentration of the first element in the second electrode region being higher than a first concentration of the first element in the first electrode region.

### Technical Proposal 2

The semiconductor device according to Technical proposal 1, wherein
the third electrode further includes a third electrode region,
a part of the second semiconductor portion is provided between the fifth partial region and the third electrode region in the second direction, and
the third electrode region includes the first element, or a third concentration of the first element in the third electrode region is higher than the first concentration.

### Technical Proposal 3

The semiconductor device according to Technical proposal 2, wherein
the third electrode further includes a fourth electrode region,
the fourth electrode region is provided between the second electrode region and the third electrode region in the first direction, and
the fourth electrode region includes the first element, or a fourth concentration of the first element in the fourth electrode region is higher than the first concentration.

### Technical Proposal 4

The semiconductor device according to Technical proposal 2, wherein
the third electrode further includes a fourth electrode region,
the fourth electrode region is provided between the second electrode region and the third electrode region in the first direction, and
the fourth electrode region does not include the first element, or a fourth concentration of the first element in the fourth electrode region is lower than the second concentration and lower than the third concentration.

### Technical Proposal 5

The semiconductor device according to Technical proposal 3 or 4, wherein
the first electrode region includes a second element including at least one selected from the group consisting of B and Al, and
the second electrode region does not include the second element, or a concentration of the second element in the second electrode region is lower than a concentration of the second element in the first electrode region.

### Technical Proposal 6

The semiconductor device according to Technical proposal 5, wherein
the second concentration is higher than the concentration of the second element in the second electrode region.

### Technical Proposal 7

The semiconductor device according to Technical proposal 3 or 4, wherein
the first electrode region includes a second element including at least one selected from the group consisting of B and Al, and
the fourth electrode region does not include the second element, or a concentration of the second element in the fourth electrode region is lower than a concentration of the second element in the first electrode region.

### Technical Proposal 8

The semiconductor device according to Technical proposal 7, wherein
the fourth concentration is higher than the concentration of the second element in the fourth electrode region.

### Technical Proposal 9

The semiconductor device according to any one of Technical proposals 1-4, wherein
the third electrode includes a second element including at least one selected from the group consisting of B and Al.

### Technical Proposal 10

The semiconductor device according to Technical proposal 9, wherein
a concentration of the second element in the third electrode is not less than 1×10¹⁷ cm⁻³ and not more than 1×10²¹ cm⁻³.

### Technical Proposal 11

The semiconductor device according to any one of Technical proposals 1-10, wherein
the second concentration is not less than 10 times and not more than 1000 times the first concentration.

### Technical Proposal 12

The semiconductor device according to any one of Technical proposals 1-11, wherein
the second concentration is not less than 1×10¹⁶ cm⁻³ and not more than 1×10²¹ cm⁻³.

### Technical Proposal 13

The semiconductor device according to any one of Technical proposals 1-12, wherein
the first concentration is less than 1×10¹⁶ cm⁻³.

### Technical Proposal 14

The semiconductor device according to any one of Technical proposals 1-13, wherein
the first insulating member includes a first insulating region, a second insulating region, and a third insulating region,
the first insulating region is provided between the third partial region and the first electrode region in the second direction,
the second insulating region is provided between the first semiconductor portion and the first electrode region in the first direction, and
the third insulating region is provided between the first electrode region and the second semiconductor portion in the first direction.

### Technical Proposal 15

The semiconductor device according to Technical proposal 14, further comprising:
a first compound member including Al_{z1}Ga_{1-z1}N (0<z1≤1, x2<z1),
the first compound member including a first compound region, and
the first compound region being provided between the third partial region and the first insulating region.

### Technical Proposal 16

The semiconductor device according to Technical proposal 15, wherein
the first compound member further includes a second compound region and a third compound region,
the second compound region is provided between the first semiconductor portion and the first insulating region, and
the third compound region is provided between the third insulating region and the second semiconductor portion.

### Technical Proposal 17

The semiconductor device according to Technical proposal 2, wherein
the first insulating member includes a fourth insulating region and a fifth insulating region,
at least a part of the fourth insulating region is provided between the first semiconductor portion and the second electrode region in the second direction, and
at least a part of the fifth insulating region is provided between the second semiconductor portion and the third electrode region in the second direction.

### Technical Proposal 18

The semiconductor device according to any one of Technical proposals 1-17, further comprising:
a second insulating member,
the second insulating member including a first insulating portion and a second insulating portion,
the first semiconductor portion being provided between the fourth partial region and the first insulating portion in the second direction, and
the second semiconductor portion being provided between the fifth partial region and the second insulating portion in the second direction.

### Technical Proposal 19

The semiconductor device according to any one of Technical proposals 1-18, wherein
a part of the first electrode region is provided between the fourth partial region and the fifth partial region in the first direction.

### Technical Proposal 20

The semiconductor device according to any one of Technical proposals 1-19, wherein
the first electrode is electrically connected to the first semiconductor portion, and
the second electrode is electrically connected to the second semiconductor portion.

According to the embodiment, a semiconductor device with improved characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor device such as semiconductor members, semiconductor layers, electrodes, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode including silicon, a position of the third electrode in a first direction from the first electrode to the second electrode being between a position of the first electrode in the first direction and a position of the second electrode in the first direction, the third electrode including a first electrode region and a second electrode region;
a semiconductor member including a first semiconductor layer and a second semiconductor layer,
the first semiconductor layer including Alₓ₁Ga₁₋ₓ₁N (0≤x1<1), the first semiconductor layer including a first partial region, a second partial region, a third partial region, a fourth partial region, and a fifth partial region, a second direction from the first partial region to the first electrode crossing the first direction, a direction from the second partial region to the second electrode being along the second direction, a direction from the third partial region to the first electrode region being along the second direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction,
the second semiconductor layer including Alₓ₂Ga₁₋ₓ₂N (0<x2≤1, x 1<x2), the second semiconductor layer including a first semiconductor portion and a second semiconductor portion, a direction from the fourth partial region to the first semiconductor portion being along the second direction, a direction from the fifth partial region to the second semiconductor portion being along the second direction, the first electrode region being between the first semiconductor portion and the second semiconductor portion in the first direction, a part of the first semiconductor portion being provided between the fourth partial region and the second electrode region in the second direction; and
a first insulating member provided between the semiconductor member and the third electrode,
the first electrode region and the second electrode region satisfying a first condition or a second condition,
in the first condition, the second electrode region including a first element including at least one selected from the group consisting of P and As, and the first electrode region not including the first element, and
in the second condition, a second concentration of the first element in the second electrode region being higher than a first concentration of the first element in the first electrode region.

2. The device according to claim 1, wherein
the third electrode further includes a third electrode region,
a part of the second semiconductor portion is provided between the fifth partial region and the third electrode region in the second direction, and
the third electrode region includes the first element, or a third concentration of the first element in the third electrode region is higher than the first concentration.

3. The device according to claim 2, wherein
the third electrode further includes a fourth electrode region,
the fourth electrode region is provided between the second electrode region and the third electrode region in the first direction, and
the fourth electrode region includes the first element, or a fourth concentration of the first element in the fourth electrode region is higher than the first concentration.

4. The device according to claim 2, wherein
the third electrode further includes a fourth electrode region,
the fourth electrode region is provided between the second electrode region and the third electrode region in the first direction, and
the fourth electrode region does not include the first element, or a fourth concentration of the first element in the fourth electrode region is lower than the second concentration and lower than the third concentration.

5. The device according to claim 3, wherein
the first electrode region includes a second element including at least one selected from the group consisting of B and Al, and
the second electrode region does not include the second element, or a concentration of the second element in the second electrode region is lower than a concentration of the second element in the first electrode region.

6. The device according to claim 5, wherein
the second concentration is higher than the concentration of the second element in the second electrode region.

7. The device according to claim 3, wherein
the first electrode region includes a second element including at least one selected from the group consisting of B and Al, and
the fourth electrode region does not include the second element, or a concentration of the second element in the fourth electrode region is lower than a concentration of the second element in the first electrode region.

8. The device according to claim 7, wherein
the fourth concentration is higher than the concentration of the second element in the fourth electrode region.

9. The device according to claim 1, wherein
the third electrode includes a second element including at least one selected from the group consisting of B and Al.

10. The device according to claim 9, wherein
a concentration of the second element in the third electrode is not less than 1×10¹⁷ cm⁻³ and not more than 1×10²¹ cm⁻³.

11. The device according to claim 1, wherein
the second concentration is not less than 10 times and not more than 1000 times the first concentration.

12. The device according to claim 1, wherein
the second concentration is not less than 1×10¹⁶ cm⁻³ and not more than 1×10²¹ cm⁻³.

13. The device according to claim 1, wherein
the first concentration is less than 1×10¹⁶ cm⁻³.

14. The device according to claim 1, wherein
the first insulating member includes a first insulating region, a second insulating region, and a third insulating region,
the first insulating region is provided between the third partial region and the first electrode region in the second direction,
the second insulating region is provided between the first semiconductor portion and the first electrode region in the first direction, and
the third insulating region is provided between the first electrode region and the second semiconductor portion in the first direction.

15. The device according to claim 14, further comprising:
a first compound member including Al_{z1}Ga_{1-z1}N (0<z 1≤1, x2<z1),
the first compound member including a first compound region, and
the first compound region being provided between the third partial region and the first insulating region.

16. The device according to claim 15, wherein
the first compound member further includes a second compound region and a third compound region,
the second compound region is provided between the first semiconductor portion and the first insulating region, and
the third compound region is provided between the third insulating region and the second semiconductor portion.

17. The device according to claim 2, wherein
the first insulating member includes a fourth insulating region and a fifth insulating region,
at least a part of the fourth insulating region is provided between the first semiconductor portion and the second electrode region in the second direction, and
at least a part of the fifth insulating region is provided between the second semiconductor portion and the third electrode region in the second direction.

18. The device according to claim 1, further comprising:
a second insulating member,
the second insulating member including a first insulating portion and a second insulating portion,
the first semiconductor portion being provided between the fourth partial region and the first insulating portion in the second direction, and
the second semiconductor portion being provided between the fifth partial region and the second insulating portion in the second direction.

19. The device according to claim 1, wherein
a part of the first electrode region is provided between the fourth partial region and the fifth partial region in the first direction.

20. The device according to claim 1, wherein
the first electrode is electrically connected to the first semiconductor portion, and
the second electrode is electrically connected to the second semiconductor portion.
